(19) United States
(12) Patent Application Publication
(10) Pub. No.: US 2025/0359015 A1
(43) Pub. Date: Nov. 20, 2025

(54) THREE-DIMENSIONAL SEMICONDUCTOR DEVICE AND METHOD OF FABRICATING THE SAME

(71) Applicant: Samsung Electronics Co., Ltd., Suwon-si (KR)

(72) Inventors: Sung-Hwan Jang, Suwon-si (KR); Bitna Kim, Suwon-si (KR)

(21) Appl. No.: 18/989,210

(22) Filed: Dec. 20, 2024

(30) Foreign Application Priority Data
May 17, 2024 (KR) 10-2024-0064303

(51) Int. Cl. H10B 12/00

(52) U.S. Cl. CPC H10B 12/30; H10B 12/05

(57) ABSTRACT

A three-dimensional semiconductor device includes a plurality of semiconductor patterns that are stacked in a first direction perpendicular to a top surface of a substrate and extend in a second direction parallel to the top surface of the substrate, a plurality of word lines on the semiconductor patterns and extending in a third direction that is parallel to the top surface of the substrate and intersects the second direction, a data storage pattern on second end portions of the semiconductor patterns and extending in the first direction, and an epitaxial pattern on first end portions of the semiconductor patterns and extending in the first direction. The semiconductor patterns are electrically connected to each other by the epitaxial pattern.

### CROSS-REFERENCE TO RELATED APPLICATIONS

This U.S. non-provisional patent application claims priority under 35 U.S.C. § 119 to Korean Patent Application No. 10-2024-0064303, filed on May 17, 2024, in the Korean Intellectual Property Office, the entire contents of which are hereby incorporated by reference.

### FIELD

The present disclosure relates to a three-dimensional semiconductor device and a method of fabricating the same, and in particular, to a highly reliable, highly integrated three-dimensional semiconductor device.

### BACKGROUND

Due to their small size, multifunctionality, and/or low-cost characteristics, semiconductor devices may be important elements in the electronics industry. Semiconductor devices may be classified into a semiconductor memory device for storing data, a semiconductor logic device for processing data, and a hybrid semiconductor device including both memory and logic elements.

With demand for high speed and low power consumption of electronic devices, semiconductor devices in the electronic devices may likewise be required to have high operating speeds and/or low operating voltages, and in order to satisfy this requirements, it may be necessary to increase an integration density of the semiconductor device. However, as the integration density of the semiconductor device increases, the semiconductor device may suffer from deteriorated electrical characteristics and/or low production yield. Accordingly, research is being conducted to improve the electrical characteristics and production yield of the semiconductor device.

### SUMMARY

An embodiment of the inventive concept provides a three-dimensional semiconductor device with improved production yield.

According to an embodiment of the inventive concept, a three-dimensional semiconductor device may include a plurality of semiconductor patterns that are stacked in a first direction perpendicular to a top surface of a substrate and extend in a second direction parallel to the top surface of the substrate, each of the semiconductor patterns including a first end portion and a second end portion that is opposite the first end portion, a plurality of word lines on the semiconductor patterns and extending in a third direction that is parallel to the top surface of the substrate and intersects the second direction, a data storage pattern on the second end portions of the semiconductor patterns and extending in the first direction, and an epitaxial pattern on the first end portions of the semiconductor patterns and extending in the first direction. The semiconductor patterns may be electrically connected to each other by the epitaxial pattern.

According to an embodiment of the inventive concept, a three-dimensional semiconductor device may include a plurality of semiconductor patterns that are stacked in a first direction perpendicular to a top surface of a substrate and extend in a second direction parallel to the top surface of the substrate, each of the semiconductor patterns including a first end portion and a second end portion that is opposite the first end portion, a plurality of word lines on the semiconductor patterns and extending in a third direction that is parallel to the top surface of the substrate and intersects the second direction, a data storage pattern on the second end portions of the semiconductor patterns and extending in the first direction, an epitaxial pattern on the first end portions of the semiconductor patterns and extending in the first direction, and a bit line wire on a top surface of the epitaxial pattern. The semiconductor patterns may be electrically connected to the bit line wire by the epitaxial pattern.

According to an embodiment of the inventive concept, a three-dimensional semiconductor device may include a substrate, and a first stack and a second stack on the substrate and adjacent to one another in a second direction that is parallel to a top surface of the substrate. The first stack may include a plurality of semiconductor patterns that are stacked in a first direction perpendicular to the top surface of a substrate and extend in the second direction, each of the semiconductor patterns including a first end portion and a second end portion that is opposite the first end portion, a word lines on the semiconductor patterns and extending in a third direction that is parallel to the top surface of the substrate and intersects the second direction, a data storage pattern on the second end portions of the semiconductor patterns and extending in the first direction, and an epitaxial pattern on the first end portions of the semiconductor patterns and extending in the first direction. The semiconductor patterns may be electrically connected to each other through the epitaxial pattern.

### BRIEF DESCRIPTION OF THE DRAWINGS

FIG. 1 is a circuit diagram schematically illustrating a three-dimensional semiconductor device according to an embodiment of the inventive concept.

FIGS. 2A, 2B, and 2C are perspective views schematically illustrating a three-dimensional semiconductor device, according to an embodiment of the inventive concept.

FIG. 3 is a plan view illustrating a three-dimensional semiconductor device according to an embodiment of the inventive concept.

FIG. 4 is a sectional view taken along a line A-A′ of FIG. 3.

FIG. 5 is an enlarged sectional view illustrating a portion ‘P1’ of FIG. 4.

FIG. 6 is a plan view illustrating a three-dimensional semiconductor device according to an embodiment of the inventive concept.

FIG. 7 is a sectional view taken along a line A-A′ of FIG. 6.

FIG. 8 is a plan view illustrating a three-dimensional semiconductor device according to an embodiment of the inventive concept.

FIG. 9 is a sectional view taken along a line A-A′ of FIG. 8.

FIG. 10 is a sectional view taken along a line A-A′ of FIG. 3.

FIGS. 11, 12, 13, 14, 15, 16, 17, 18, 19, and 20 are diagrams illustrating a method of fabricating a three-dimensional semiconductor device, according to an embodiment of the inventive concept.

### DETAILED DESCRIPTION

Example embodiments of the inventive concepts will now be described more fully with reference to the accompanying drawings, in which example embodiments are shown. Like reference numerals in the drawings denote like elements, and thus their description will be omitted. The terms “first,” “second,” etc., may be used herein merely to distinguish one component, layer, direction, etc. from another. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly” on, or “in direct contact” or “directly connected,” no intervening components or layers are present.

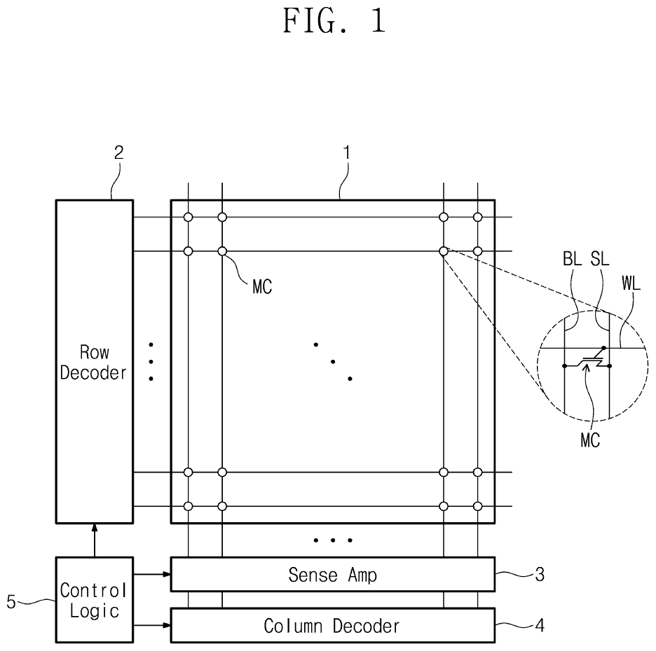

FIG. 1 is a circuit diagram schematically illustrating a three-dimensional semiconductor device according to an embodiment of the inventive concept.

Referring to FIG. 1, a three-dimensional semiconductor device may include a memory cell array 1, a row decoder 2, a sense amplifier 3, a column decoder 4, and a control logic 5.

The memory cell array 1 may include word lines WL, bit lines BL, source lines SL, and memory cells MC. The memory cells MC may be three-dimensionally arranged, and each memory cell MC may be connected to one of the word lines WL, one of the bit lines BL, and one of the source lines SL. In an embodiment, each of the memory cells MC may be composed of one transistor including a memory layer or a data storing layer.

The row decoder 2 may be configured to decode address information, which is input from the outside, and to select one of the word lines WL of the memory cell array 1, based on the decoded address information. The address information decoded by the row decoder 2 may be provided to a row driver (not shown), and in this case, the row driver may provide respective voltages to the selected one of the word lines WL and the unselected ones of the word lines WL, in response to the control of the control logic 5.

The sense amplifier 3 may be configured to sense, amplify, and output a difference in voltage between one of the bit lines BL, which is selected based on address information decoded by the column decoder 4, and a reference bit line.

The column decoder 4 may establish a data transmission path between the sense amplifier 3 and an external device (e.g., a memory controller). The column decoder 4 may be configured to decode address information, which is input from the outside, and to select one of the bit lines BL, based on the decoded address information.

The control logic 5 may be configured to generate control signals, which are used to control data-writing or data-reading operations on the memory cell array 1.

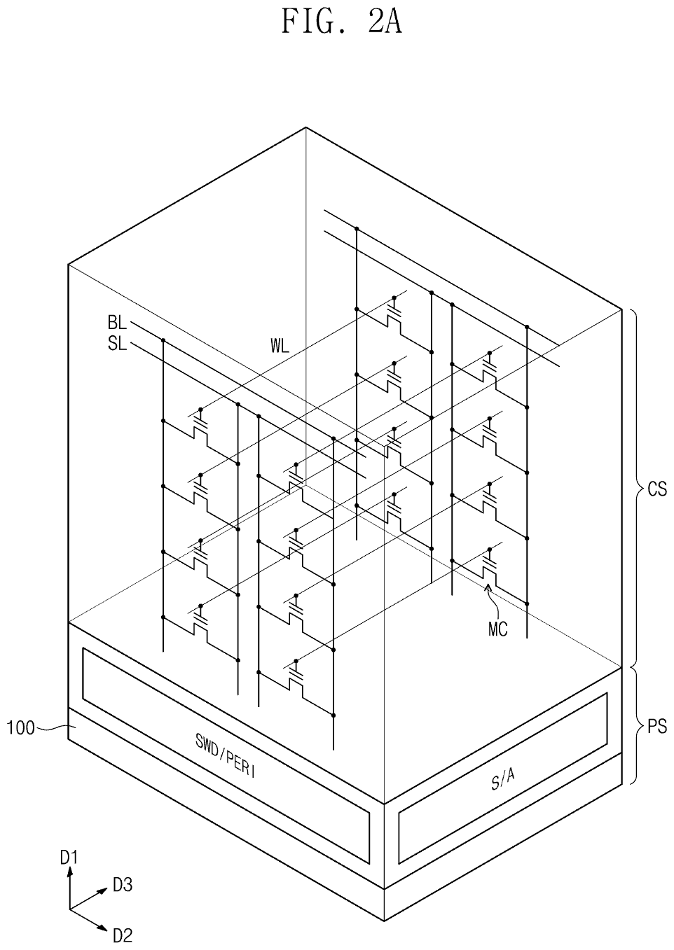

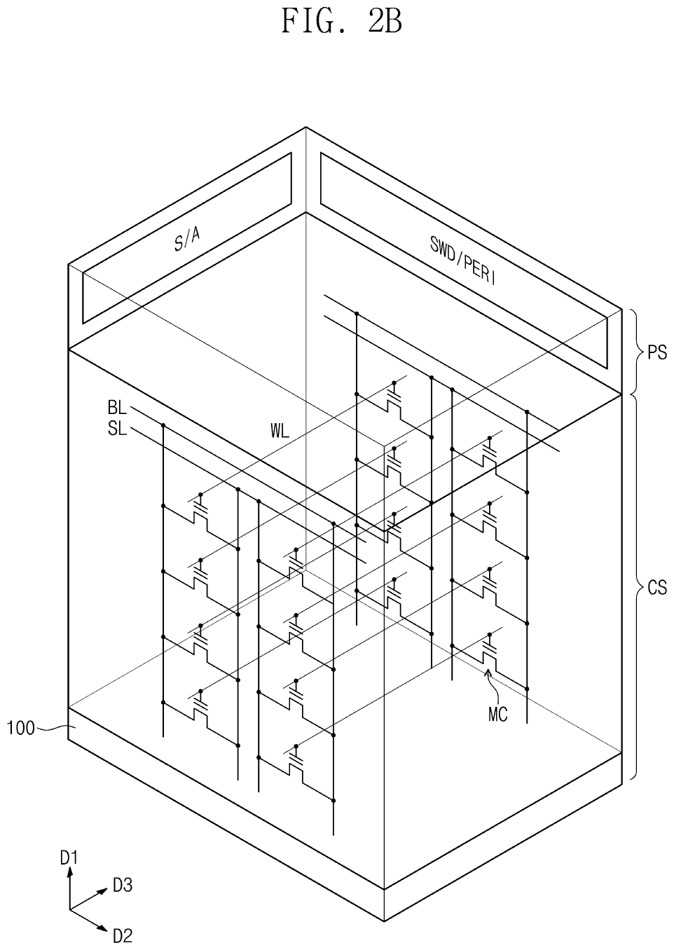

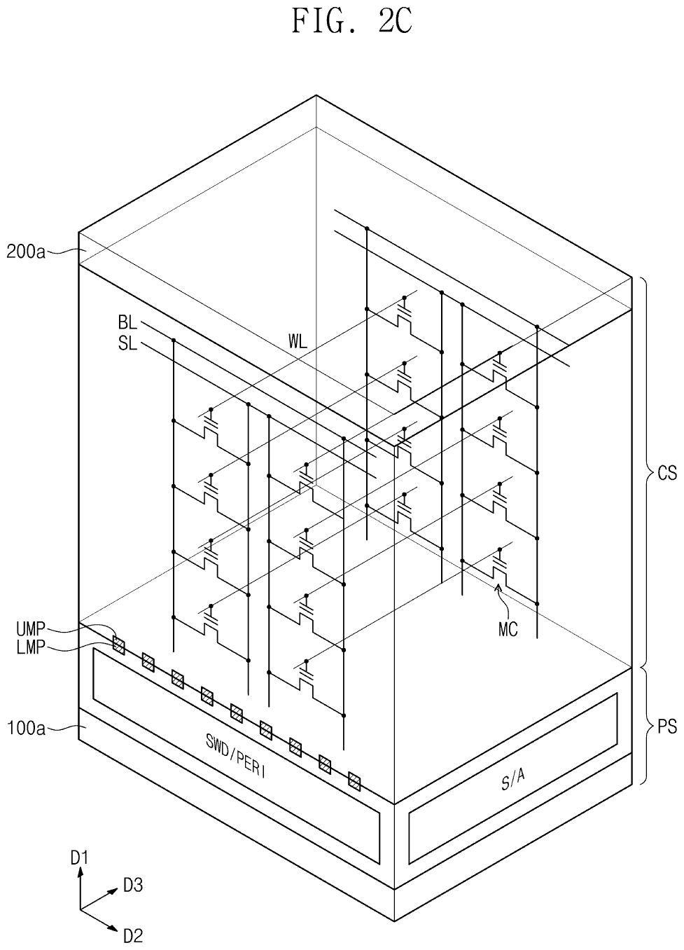

FIGS. 2A, 2B, and 2C are perspective views schematically illustrating a three-dimensional semiconductor device, according to an embodiment of the inventive concept.

Referring to FIG. 2A, a three-dimensional semiconductor device may include a substrate 100, a peripheral circuit structure PS on the substrate 100, and a cell array structure CS on the peripheral circuit structure PS, such that the peripheral circuit structure PS is between the cell array structure CS and the substrate 100.

The peripheral circuit structure PS may include core and peripheral circuits, which are formed on the substrate 100. The core and peripheral circuits may include the row and column decoders 2 and 4, the sense amplifier 3, and the control logic 5 described with reference to FIG. 1.

The peripheral circuit structure PS and the cell array structure CS may be sequentially stacked on the substrate 100 in a first direction D1 perpendicular to a top surface of the substrate 100. The substrate 100 may be a planar or plate-shaped structure that extends parallel to a plane defined by a second direction D2 and a third direction D3. The second and third directions D2 and D3 may be parallel to the top surface of the substrate 100 and may not be parallel to each other. That is, the second and third directions D2 and D3 may intersect one another.

The cell array structure CS may include the bit lines BL, the source lines SL, the word lines WL, and the memory cells MC therebetween. Each of the memory cells MC may be connected to one of the word lines WL, one of the bit lines BL, and one of the source lines SL.

Referring to FIG. 2B, the semiconductor device may include the cell array structure CS on the substrate 100 and the peripheral circuit structure PS on the cell array structure CS. The cell array structure CS may be disposed between the substrate 100 and the peripheral circuit structure PS. The peripheral circuit structure PS may include the core and peripheral circuits.

Referring to FIG. 2C, the semiconductor device may have a chip-to-chip (C2C) structure. The peripheral circuit structure PS may include the first substrate 100a. Lower metal pads LMP may be provided in the uppermost portion of the peripheral circuit structure PS. The lower metal pads LMP may be electrically connected to the core and peripheral circuits. The lower metal pads LMP may be bonded to upper metal pads UMP of the cell array structure CS. Spatially relative terms such as ‘on,’ ‘above,’ ‘upper,’ ‘beneath,’ ‘below,’ ‘lower,’ ‘side,’ and the like may be used herein to describe elements or features with reference to the drawings. However, it will be understood that such spatially relative terms are intended to encompass different orientations of the device in use or operation in addition to the orientation depicted in the figures. For example, if the device in the figures is turned over, elements described as below or beneath other elements or features would then be oriented above the other elements or features.

The cell array structure CS may include a second substrate 200a, and the upper metal pads UMP may be provided in the lowermost portion of the cell array structure CS. The upper metal pads UMP may be electrically connected to the bit lines BL, the source lines SL, and the word lines WL. The upper metal pads UMP may be electrically connected to the memory cells MC.

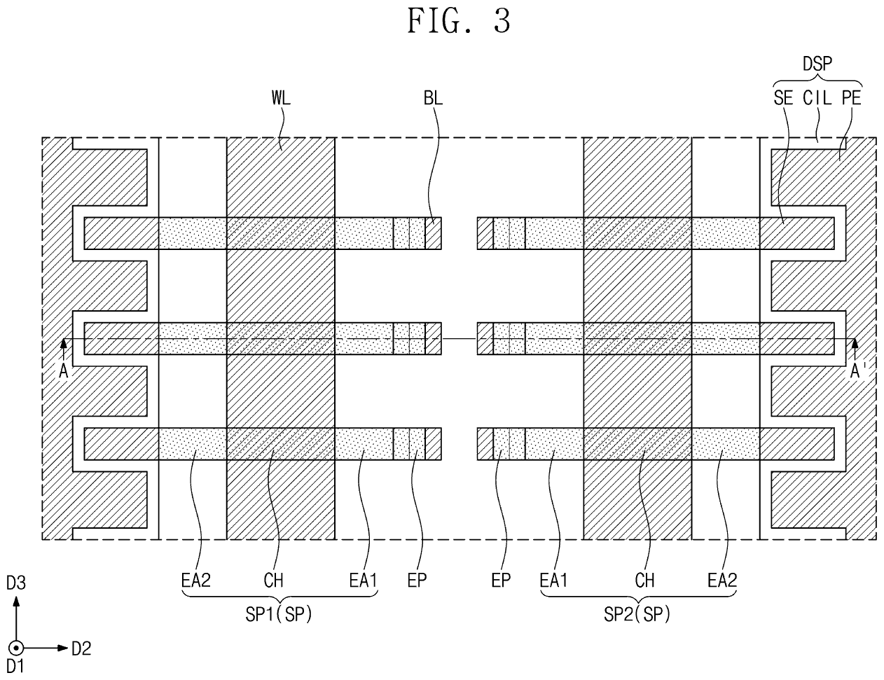

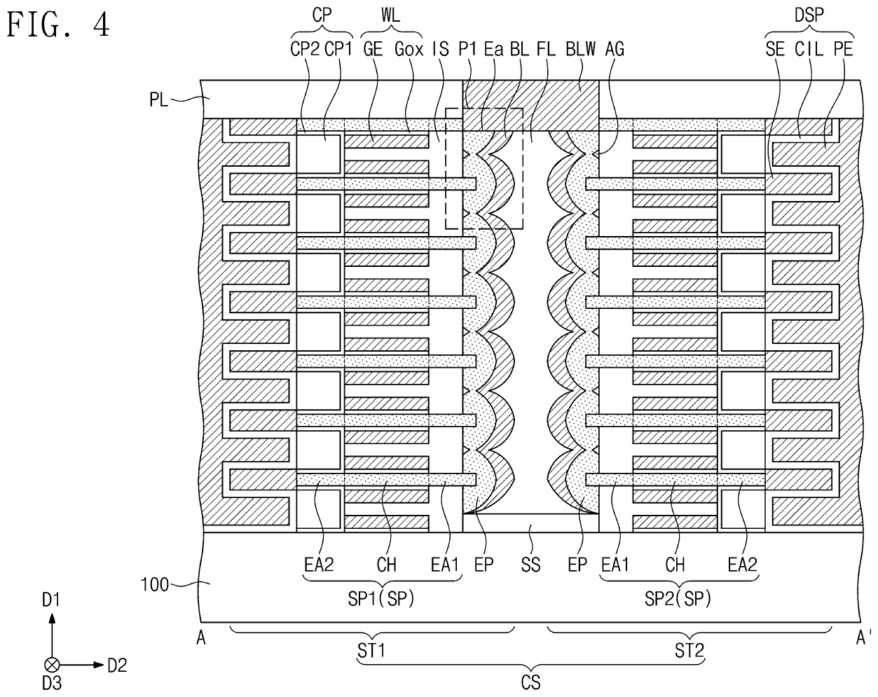

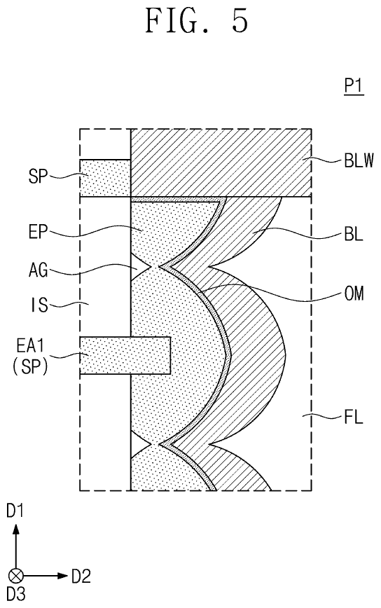

FIG. 3 is a plan view illustrating a three-dimensional semiconductor device according to an embodiment of the inventive concept. FIG. 4 is a sectional view taken along a line A-A′ of FIG. 3. FIG. 5 is an enlarged sectional view illustrating a portion ‘P1’ of FIG. 4.

Referring to FIGS. 3 and 4, the three-dimensional semiconductor device may include the substrate 100. In an embodiment, the substrate 100 may be a semiconductor substrate, an insulating substrate, a silicon-on-insulator (SOI) substrate, or a germanium-on-insulator (GOI) substrate. The semiconductor substrate may be, for example, a silicon substrate, a germanium substrate, or a silicon-germanium substrate. The substrate 100 may be a planar or plate-shaped structure that extends in the second and third directions D2 and D3.

The cell array structure CS may be provided on the substrate 100. The cell array structure CS may include a first stack ST1 and a second stack ST2, which are adjacent to each other in the second direction D2. In an embodiment, although not shown, the cell array structure CS may include a plurality of cell array structures CS, which are adjacent to each other in the second direction D2. Hereinafter, just one cell array structure CS will be described for brevity, but the others of the cell array structures CS may also have substantially the same features as described below.

Each of the first and second stacks ST1 and ST2 may include semiconductor patterns SP, an epitaxial pattern EP, word lines WL, bit lines BL, a capping pattern CP, a data storage pattern DSP, and an inner insulating layer IS. In an embodiment, the first and second stacks ST1 and ST2 may exhibit mirror symmetry with respect to a filling pattern FL, which will be described below.

The semiconductor pattern SP may be spaced apart from the substrate 100 in the first direction D1. That is, the semiconductor pattern SP may be floated from or electrically floating with respect to the substrate 100. The semiconductor pattern SP may extend in the second direction D2, on the substrate 100. In an embodiment, the semiconductor pattern SP may be a bar-shaped pattern, which extends in the second direction D2.

The semiconductor pattern SP may include a first edge portion EA1 and a second edge portion EA2, which are spaced apart from each other (e.g., on opposing ends of the semiconductor pattern SP) in the second direction D2, and a channel region CH, which is provided therebetween. The channel region CH of the semiconductor pattern SP may be surrounded by a word line WL, which will be described below. The term “surround” or “cover” or “fill” or “enclose” as may be used herein may not require completely surrounding or covering or filling or enclosing the described elements or layers, but may, for example, refer to partially surrounding or covering or filling or enclosing the described elements or layers. The first edge portion EA1 of the semiconductor pattern SP may be adjacent to an epitaxial pattern EP and a bit line BL, which will be described below. The first edge portion EA1 may be connected to the bit line BL. The second edge portion EA2 may be adjacent to the data storage pattern DSP. The second edge portion EA2 may be connected to the data storage pattern DSP. In the present specification, the expression “elements A and B are connected” may be used to indicate that elements A and B are either directly connected to each other or indirectly connected through another element C (e.g., a conductive element) therebetween. Here, the element C may be a single element or a plurality of elements.

The semiconductor pattern SP may be formed of or include at least one of single-crystalline semiconductor materials, polycrystalline semiconductor materials, oxide semiconductor materials, and two-dimensional materials. In an embodiment, the single-crystalline semiconductor material may be single-crystalline silicon. In an embodiment, the polycrystalline semiconductor materials may be poly silicon. In an embodiment, the oxide semiconductor materials may be indium gallium zinc oxide (IGZO). In an embodiment, the two-dimensional material may be MoS₂, WS₂, MoSe₂, or WSe₂. In the present specification, the expressions of “A or B”, “at least one of A and B”, “at least one of A or B”, “A, B, or C”, “at least one of A, B, and C”, and “at least one of A, B, or C” may be used to represent one of the elements enumerated in the expression or any possible combination of the enumerated elements.

In an embodiment, each of the first and second edge portions EA1 and EA2 of the semiconductor pattern SP may include an impurity region doped with impurities (e.g., n- or p-type impurities). The impurity region may constitute a source region or a drain region (which may collectively be referred to as a “source/drain region”) of a transistor.

In an embodiment, a plurality of semiconductor patterns SP may be provided. The semiconductor patterns SP may be arranged in the first direction D1 (e.g., a vertical direction) and the third direction D3 (e.g., a horizontal direction). The semiconductor patterns SP, which are arranged in the first direction D1, may be vertically overlapped with each other in the first direction D1. Components or layers described with reference to “overlap” in a particular direction may be at least partially obstructed by one another when viewed along a line extending in the particular direction or in a plane perpendicular to the particular direction. Side surfaces of the semiconductor patterns SP arranged in the first direction D1 may be vertically aligned to each other along the first direction D1.

The semiconductor pattern SP may include a first semiconductor pattern SP1, which is provided in the first stack ST1, and a second semiconductor pattern SP2, which is provided in the second stack ST2. The first semiconductor pattern SP1 may be adjacent to the second semiconductor pattern SP2 in the second direction D2 (e.g., in a horizontal direction). For the first semiconductor pattern SP1, the second and first edge portions EA2 and EA1 may be sequentially arranged in the second direction D2. For the second semiconductor pattern SP2, the first and second edge portions EA1 and EA2 may be sequentially arranged in the second direction D2.

The word line WL may be provided to surround the channel region CH of the semiconductor pattern SP and may extend in the third direction D3. In an embodiment, the word line WL may have a structure fully surrounding the channel region CH of the semiconductor pattern SP (i.e., a gate-all-around structure). The word line WL may surround the channel region CH of each of the semiconductor patterns SP, which are adjacent to each other in the third direction D3. In an embodiment, a plurality of word lines WL may be provided. Each of the word lines WL may be provided to surround the channel region CH of a corresponding one of the semiconductor patterns SP, which are adjacent to each other in the first direction D1, and may extend in the third direction D3.

The word line WL may include a gate dielectric layer Gox, which is provided to enclose the channel region CH of the semiconductor pattern SP, and a gate electrode GE, which is provided on the gate dielectric layer Gox to enclose the channel region CH of the semiconductor pattern SP.

In an embodiment, the gate dielectric layer Gox may be formed of or include at least one of high-k dielectric materials, silicon oxide, silicon nitride, or silicon oxynitride and may be provided to have a single- or multi-layered structure. In the present specification, the high-k dielectric material may be defined as a material having a dielectric constant higher than silicon oxide.

In an embodiment, the gate electrode GE may include at least one of Ti, TiN, TiSiN, TION, W, WN, Mo, MON, MoOxNy, Ta, TaN, Poly Si, Li, Na, K, Cs, Rb, Sr, Ba, Ca, Ce, Sm, Eu, Mg, Sc, Y, Hf, TI, As, La, Nd, Gd, Tb, Lu, Th, U, Mn, Al, Ga, In, Pb, Cd, Bi, and/or Zr. In an embodiment, the gate electrode GE may be a single layer or a composite layer.

The data storage pattern DSP may be connected to the second edge portion EA2 of each of the semiconductor patterns SP and may extend in the first direction D1. The data storage pattern DSP may be provided on the second edge portion EA2 of the first semiconductor pattern SP1 and may extend in the first direction D1. The data storage pattern DSP may be provided on the second edge portion EA2 of the second semiconductor pattern SP2 and may extend in the first direction D1.

The data storage pattern DSP may include a storage electrode SE, a plate electrode PE, and a capacitor dielectric layer CIL therebetween. In an embodiment, the three-dimensional semiconductor device may be a dynamic random access memory (DRAM) device, and here, the data storage pattern DSP may be used as a capacitor. The storage electrode SE may be spaced apart from the plate electrode PE by the capacitor dielectric layer CIL.

Each of the storage and plate electrodes SE and PE may include a conductive material. In an embodiment, each of the storage and plate electrodes SE and PE may be formed of or include at least one of doped silicon (Si), doped silicon germanium (SiGe), metallic materials (e.g., Ti, Mo, W, Cu, Al, Ta, Ru, Ir, Co, Pt, Au, and Ag), metal nitride materials (e.g., nitride materials containing Ti, Mo, W, Cu, Al, Ta, Ru, Ir, Co, Pt, Au, and Ag), titanium silicon nitride (e.g., TiSiN), titanium aluminum nitride (e.g., TiAlN), tantalum aluminum nitride (e.g., TaAlN), conductive oxide materials (e.g., PtO, RuO₂, IrO₂, SrRuO₃ (SRO), (Ba,Sr)RuO₃ (BSRO), CaRuO₃ (CRO), and LSCo), or metal silicide materials. Each of the storage and plate electrodes SE and PE may be a single layer, which is made of a single material, or a composite layer including two or more materials.

In an embodiment, the capacitor dielectric layer CIL may include at least one of metal oxide materials (e.g., HfO₂, ZrO₂, Al₂O₃, La₂O₃, Ta₂O₃, and TiO₂) and perovskite dielectric materials (e.g., SrTiO₃ (STO), (Ba,Sr)TiO₃ (BST), BaTiO₃, PZT, and PLZT).

In another embodiment, the data storage pattern DSP may be a variable resistance pattern whose resistance can be switched to one of at least two states by an electric pulse applied thereto. For example, the data storage pattern DSP may be formed of or include at least one of phase-change materials whose crystal state can be changed depending on an amount of a current applied thereto, perovskite compounds, transition metal oxides, magnetic materials, ferromagnetic materials, or antiferromagnetic materials.

Although not shown, a silicide pattern (not shown) may be provided between the storage electrode SE and the first semiconductor pattern SP1 and between the storage electrode SE and the second semiconductor pattern SP2. The silicide pattern may be formed of or include at least one of metal silicide materials (e.g., containing Ti, Mo, W, Cu, Al, Ta, Ru, Ir, and Co). In an embodiment, a plurality of storage electrodes SE may be provided to be adjacent to each other in the first direction D1.

The plate electrode PE may include a first region, which extends in the third direction D3, and a second region, which extends from the first region to protrude in the second direction D2 or the opposite direction thereof. The second region of the plate electrode PE may be interposed between the storage electrodes SE arranged in the first direction D1.

The capping pattern CP may be provided in the cell array structure CS. The capping pattern CP may be interposed between the word lines WL and the data storage pattern DSP. The capping pattern CP may be interposed between the semiconductor patterns SP, which are adjacent to each other in the first direction D1. The capping pattern CP may be interposed between the second edge portions EA2 of the semiconductor patterns SP, which are adjacent to each other in the third direction D3.

The capping pattern CP may include a first capping pattern CP1 enclosing the second edge portion EA2 of the semiconductor pattern SP and a second capping pattern CP2 on the first capping pattern CP1. The first capping pattern CP1 may conformally cover the second edge portion EA2 of the semiconductor pattern SP and a side surface of the word line WL. Each of the first and second capping patterns CP1 and CP2 may include an insulating material. The second capping pattern CP2 may be provided in the form of a single layer or a composite layer. The epitaxial pattern EP may be provided on the first edge portion EA1 of the semiconductor pattern SP and may extend in the first direction D1. In detail, the epitaxial pattern EP may be connected to the first edge portion EA1 of each of the semiconductor patterns SP, which are arranged in the first direction D1, and may extend in the first direction D1. Thus, the semiconductor patterns SP, which are stacked or arranged in the first direction D1, may be electrically connected to each other through the epitaxial pattern EP. In an embodiment, the epitaxial pattern EP may be in contact with the first edge portion EA1 of each of the semiconductor patterns SP arranged in the first direction D1. In an embodiment, the epitaxial pattern EP may be connected to the semiconductor patterns SP, which are arranged in the first direction D1, to form a single body or a unitary member.

The epitaxial pattern EP may be formed through a selective epitaxial growth (SEG) using the semiconductor pattern SP as a seed layer. In an embodiment, the epitaxial pattern EP may be formed of or include at least one of Si or SiGe. In an embodiment, in the case where the epitaxial pattern EP includes SiGe, a germanium concentration may increase as a distance from the first edge portion EA1 of the semiconductor pattern SP increases in a direction toward the bit line BL. That is, a germanium concentration of the epitaxial pattern EP may increase with distance from the first edge portion EA1 of the semiconductor pattern SP toward the bit line BL. In particular, in the case where the epitaxial pattern EP includes SiGe, due to the energy band characteristics of the epitaxial pattern EP and the semiconductor pattern SP, a hole barrier height at a junction of the epitaxial pattern EP and the semiconductor pattern SP may be lowered. Thus, it may be possible to reduce a gate induced leakage current (GIDL) phenomenon in the semiconductor pattern. As a result, an amount of holes accumulated in the semiconductor pattern may be reduced, and a leakage current caused by the holes may be reduced. Thus, the reliability of the three-dimensional semiconductor device may be improved.

The epitaxial pattern EP may contain impurities of an n conductivity type, that is, n-type impurities. In an embodiment, the n-type impurity may include at least one of P or As. In an embodiment, an atomic concentration of the n-type impurity may increase as a distance from the first edge portion EA1 of the semiconductor pattern SP increases in a direction toward the bit line BL.

Since, as described above, the epitaxial pattern EP is a pattern formed by the SEG process, the epitaxial pattern EP may have a profile that is different from a conductive pattern formed by a patterning process. For example, the epitaxial pattern EP may include convex portions which are repeatedly provided in the first direction D1. Each of the convex portions may be convex in or toward the second direction D2. That is, the epitaxial pattern EP may include a plurality of convex portions that protrude in the second direction D2 from the first end portions EA1 of the semiconductor patterns SP. A side surface of the epitaxial pattern EP may have a wavy or undulating profile in the first direction D1.

An air gap AG may be provided between the epitaxial pattern EP and the inner insulating layer IS. In an embodiment, the air gap AG may not necessarily have to contain air and may be a simple empty space, which is not filled with a solid material. An opposite side surface of the epitaxial pattern EP may be partially exposed to the air gap AG. The term exposed” may be used to describe relationships between elements and/or certain intermediate processes in fabricating a completed semiconductor device, but may not necessarily require exposure of the particular region, layer, structure or other element in the context of the completed device. The exposed opposite side surface of the epitaxial pattern EP may have a profile that is indented toward the epitaxial pattern EP. In an embodiment, a plurality of air gaps AG may be provided, and the air gaps AG may be repeatedly provided between the inner insulating layer IS and the epitaxial pattern EP in the first direction D1. That is, a plurality of air gaps AG may be arranged along the first direction D1 between the inner insulating layer IS and the epitaxial pattern EP.

In an embodiment, in the case where an interface between the semiconductor pattern SP and the epitaxial pattern EP is observable or distinguishable, the semiconductor pattern SP and the epitaxial pattern EP may have the following structural relationship. The semiconductor pattern SP may partially penetrate or extend into the epitaxial pattern EP. A portion of the semiconductor pattern SP may be inserted in the epitaxial pattern EP. In an embodiment, a portion of the first edge portion EA1 of the semiconductor pattern SP may be buried in the epitaxial pattern EP. The epitaxial pattern EP may be in contact with each of top, bottom, and side surfaces of the first edge portion EA1.

The bit line BL may be provided on a side surface of the epitaxial pattern EP. The bit line BL may extend along the side surface of the epitaxial pattern EP or in the first direction D1. The bit line BL may be spaced apart from the semiconductor pattern SP by the epitaxial pattern EP. The bit line BL may be electrically connected to the semiconductor pattern SP through the epitaxial pattern EP. In an embodiment, the bit line BL may be formed of or include at least one of metallic materials or doped poly-silicon.

The bit line BL may cover a side surface of the epitaxial pattern EP. Thus, the bit line BL may extend in the first direction D1 to have a wave or undulating shape. Opposite side surfaces of the bit line BL may have a wavy or undulating profile in the first direction D1. One of the opposite side surfaces of the bit line BL may be concave toward the second direction D2. The other of the opposite side surfaces of the bit line BL may be convex toward the second direction D2.

A bit line wire BLW may be provided on a top surface Ea of the epitaxial pattern EP. The bit line wire BLW may be provided on a top surface of the bit line BL. The bit line wire BLW may be provided in a protection layer PL, which will be described below. The bit line wire BLW may be located at substantially the same level (relative to the substrate 100) as the uppermost one of the semiconductor patterns SP, which are stacked adjacent to each other in the first direction D1. In an embodiment, the bit line wire BLW may be formed of or include at least one of metallic or conductive materials.

The bit line wire BLW may be electrically connected to the semiconductor patterns SP, which are adjacent to each other in the first direction D1, through the epitaxial pattern EP. The bit line wire BLW may be electrically connected to the bit line BL. Although not shown, the bit line wire BLW may be electrically connected to the sense amplifier 3 of FIG. 1 through separate elements.

In an embodiment, the epitaxial pattern EP may be formed through a SEG process using the semiconductor patterns SP as a seed layer, and the semiconductor patterns SP may be connected to each other through the epitaxial pattern EP. Thus, the semiconductor patterns SP may be electrically connected to the bit line wire BLW through the epitaxial pattern EP, even when an additional patterning process is not performed. If a plurality of conductive patterns are formed through a patterning process on a conductive layer extending in the third direction D3 without forming the epitaxial pattern EP, the conductive patterns adjacent to each other in the third direction D3 may not be separated and may be electrically connected to each other due to a residue of the conductive layer. In addition, when the conductive layer is formed, a seam may be formed in the conductive layer, and due to the seam, upper and lower portions of the conductive pattern, which should be connected to each other, may not be connected to each other. According to an embodiment of the inventive concept, since the semiconductor patterns SP are electrically connected to the bit line wire BLW through the epitaxial pattern EP, the above-described patterning process may be omitted. As a result, it may be possible to reduce a process failure, which may be caused by the patterning process. Thus, the productivity or production yield of the three-dimensional semiconductor device may be improved.

Referring to FIG. 5, in the case where each of the bit line BL and the bit line wire BLW includes a metallic material, an ohmic pattern OM may be interposed between the epitaxial pattern EP and the bit line BL and between the epitaxial pattern EP and the bit line wire BLW. The ohmic pattern OM may extend in the first direction D1 and may have a wavy or undulating shape. In an embodiment, the ohmic pattern OM may be formed of or include at least one of metal silicide materials (e.g., containing Ti, Mo, W, Cu, Al, Ta, Ru, Ir, or Co). Since the ohmic pattern OM is provided between the epitaxial pattern EP and the bit line BL and between the epitaxial pattern EP and the bit line wire BLW, an electrical resistance therebetween may be decreased.

Referring back to FIGS. 3 and 4, a separation pattern SS may be provided on the substrate 100. In an embodiment, the separation pattern SS may include an insulating material. The separation pattern SS may be interposed between the epitaxial pattern EP and the substrate 100 and between the bit line BL and the substrate 100. Each of the epitaxial pattern EP and the bit line BL may be separated and electrically disconnected (i.e., electrically isolated) from the substrate 100 by the separation pattern SS.

The filling pattern FL may be provided on the separation pattern SS. The filling pattern FL may be interposed between the first stack ST1 and the second stack ST2. In detail, the filling pattern FL may be interposed between the bit line BL on a side surface of the first stack ST1 and the bit line BL on a side surface of the second stack ST2. The filling pattern FL may be interposed between the separation pattern SS and the bit line wire BLW. In an embodiment, the filling pattern FL may include an insulating material.

The inner insulating layer IS may be provided on the substrate 100. The inner insulating layer IS may be interposed between the epitaxial pattern EP and the word line WL, between the semiconductor patterns SP, which are adjacent to each other in the first direction D1, between the first edge portions EA1 of the semiconductor patterns SP, which are adjacent to each other in the third direction D3, and between the word lines WL, which are adjacent to each other in the first direction D1. The inner insulating layer IS may include a single or composite layer including an insulating material.

The protection layer PL may be provided on the cell array structure CS. The protection layer PL may cover a top surface of each of the first stack ST1, the second stack ST2, the data storage pattern DSP, and the bit line wire BLW. The protection layer PL may include a single or composite layer including an insulating material. The protection layer PL may include a plurality of upper interconnection lines (not shown) provided therein. Some of the upper interconnection lines may be connected to the bit line wire BLW, and others may be connected to the data storage pattern DSP. In addition, although not shown, word line pads (not shown) may be provided on a side surface of the cell array structure CS and may be connected to the word lines WL.

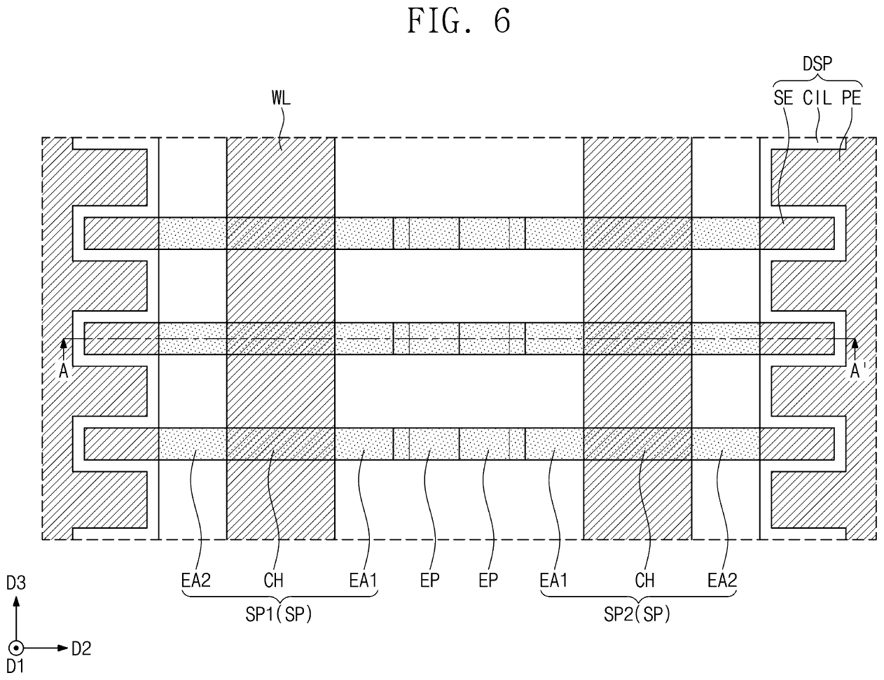

Hereinafter, a three-dimensional semiconductor device according to an embodiment of the inventive concept will be described in more detail with reference to FIGS. 6 to 10. In the following description, a previously-described element may be identified by the same reference number without repeating an overlapping description thereof, for concise description.

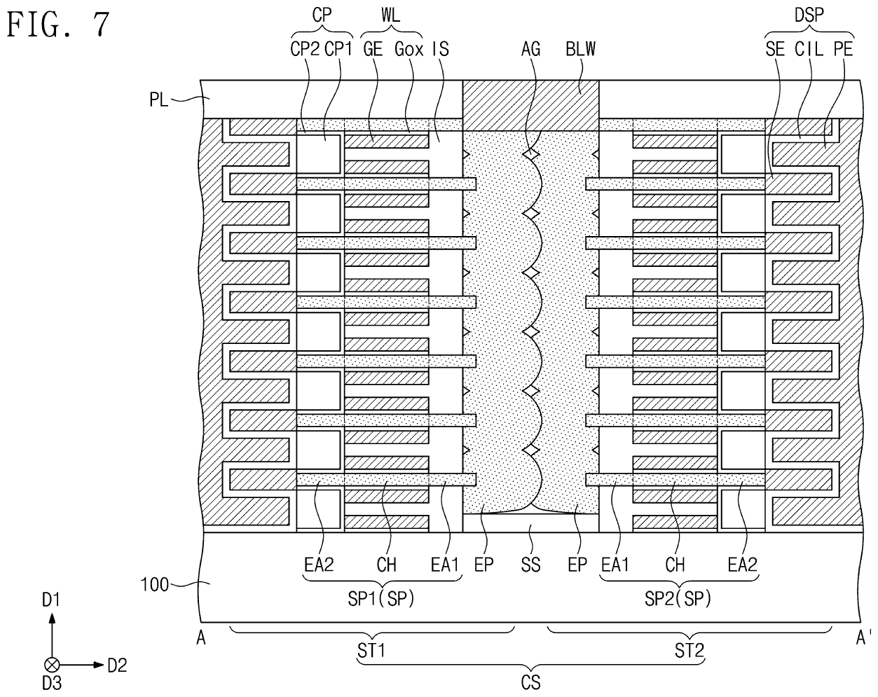

FIG. 6 is a plan view illustrating a three-dimensional semiconductor device according to an embodiment of the inventive concept. FIG. 7 is a sectional view taken along a line A-A′ of FIG. 6.

Referring to FIGS. 6 and 7, the bit line BL and the filling pattern FL may be omitted, in contrast to that described with reference to FIGS. 3 to 5. The epitaxial pattern EP may be formed larger than that described with reference to FIGS. 3 to 5. Thus, the epitaxial pattern EP on the first stack ST1 and the epitaxial pattern EP on the second stack ST2 may be in contact with each other. The epitaxial pattern EP on the first stack ST1 and the epitaxial pattern EP on the second stack ST2 may fill a region, from which the bit line BL and the filling pattern FL are omitted.

The air gaps AG may be further provided between the epitaxial pattern EP on the first stack ST1 and the epitaxial pattern EP on the second stack ST2. The epitaxial pattern EP on the first stack ST1 and the epitaxial pattern EP on the second stack ST2 are illustrated to be in contact with each other with an interface therebetween, but the inventive concept is not limited to this example. In an embodiment, the epitaxial pattern EP on the first stack ST1 and the epitaxial pattern EP on the second stack ST2 may be connected to form a single body or unitary member.

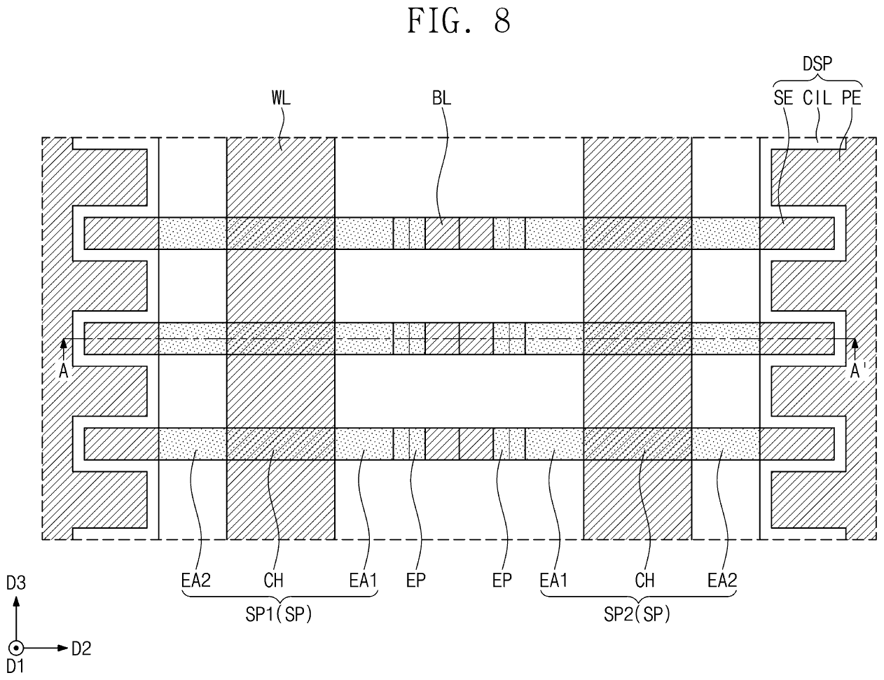

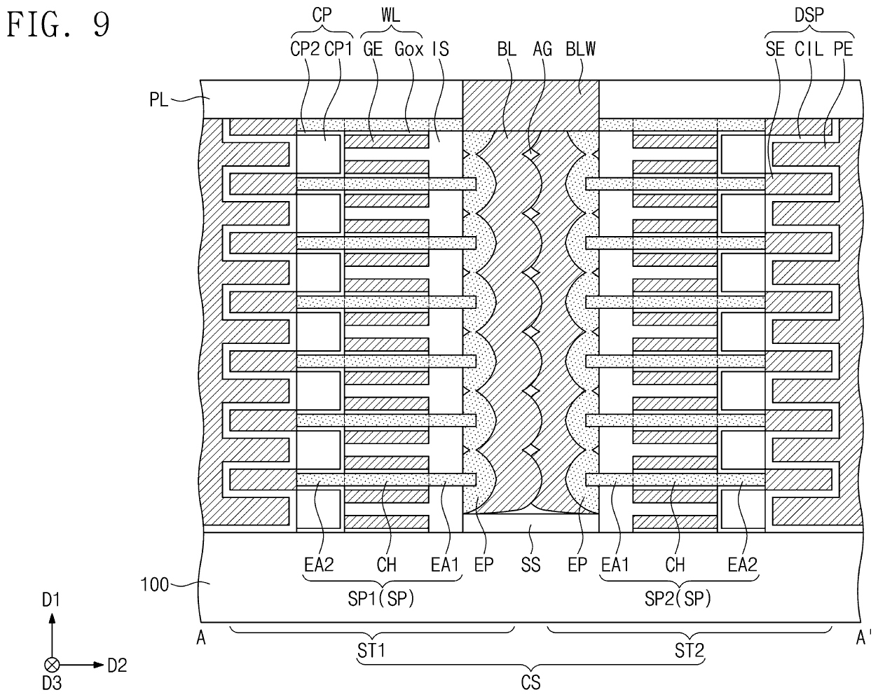

FIG. 8 is a plan view illustrating a three-dimensional semiconductor device according to an embodiment of the inventive concept. FIG. 9 is a sectional view taken along a line A-A′ of FIG. 8.

Referring to FIGS. 8 and 9, the filling pattern FL may be omitted, in contrast to that described with reference to FIGS. 3 to 5. The bit line BL may be formed larger than that described with reference to FIGS. 3 to 5. Thus, the bit line BL on the first stack ST1 may be in contact with the bit line BL on the second stack ST2. The bit line BL on the first stack ST1 and the bit line BL on the second stack ST2 may fill a region, from which the filling pattern FL is omitted.

The air gaps AG may be further provided between the bit line BL on the first stack ST1 and the bit line BL on the second stack ST2. The bit line BL on the first stack ST1 and the bit line BL on the second stack ST2 are illustrated to be in contact with each other with an interface therebetween, but the inventive concept is not limited to this example. In an embodiment, the bit line BL on the first stack ST1 and the bit line BL on the second stack ST2 may be connected to form a single body or unitary member.

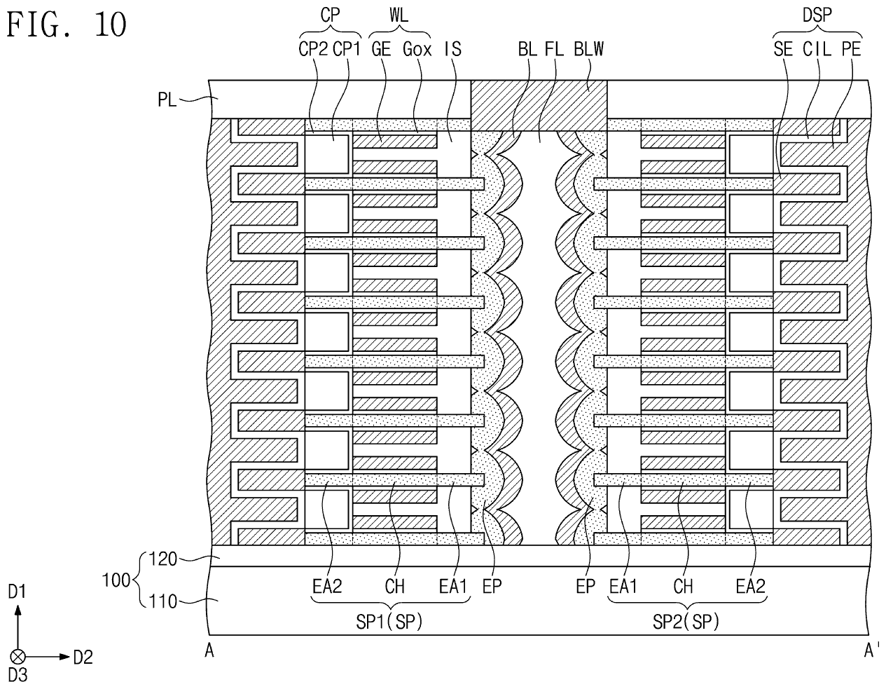

FIG. 10 is a sectional view illustrating a three-dimensional semiconductor device according to an embodiment of the inventive concept, taken along the line A-A′ of FIG. 3.

Referring to FIG. 10, the separation pattern SS may be omitted, in contrast with the structure of FIGS. 3 and 4. The substrate 100 may be a silicon-on-insulator (SOI) substrate. The substrate 100 may include a semiconductor substrate 110, which is formed of or includes a semiconductor material, and an insulating substrate 120, which is formed of or includes an insulating material and is provided on the semiconductor substrate 110. Thus, even when the separation pattern SS is omitted, each of the epitaxial pattern EP and the bit line BL may be separated and electrically disconnected (i.e., electrically isolated) from the semiconductor substrate 110 by the insulating substrate 120.

In contrast with the structure of FIGS. 3 and 4, the semiconductor pattern SP may be further interposed between the lowermost one of the word lines WL, which are adjacent to each other in the first direction D1, and the substrate 100.

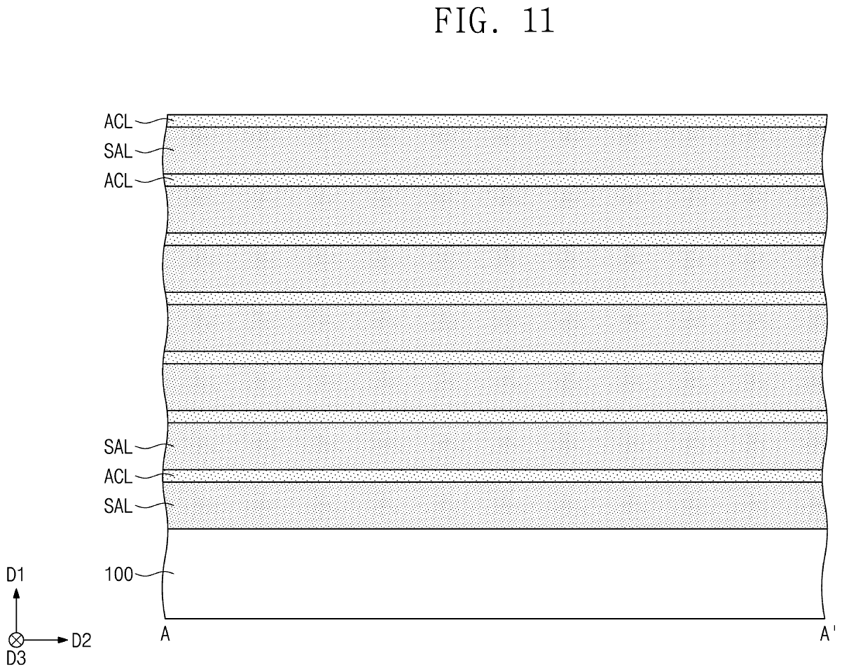

Hereinafter, a method of fabricating a three-dimensional semiconductor device, according to an embodiment of the inventive concept, will be described in more detail with reference to FIGS. 11 to 20. In the following description, a previously-described element may be identified by the same reference number without repeating an overlapping description thereof, for concise description.

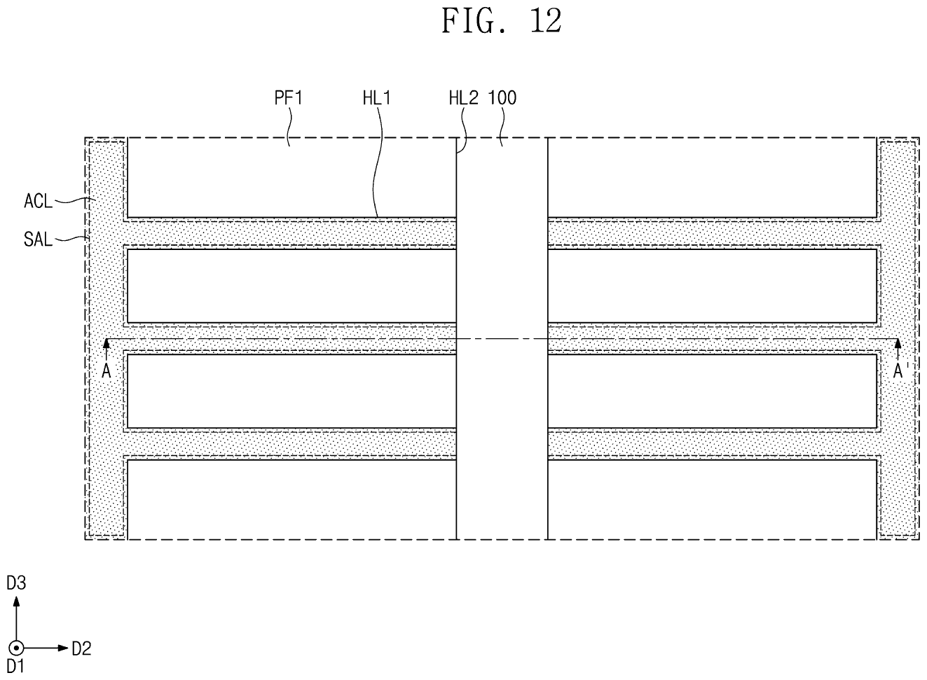

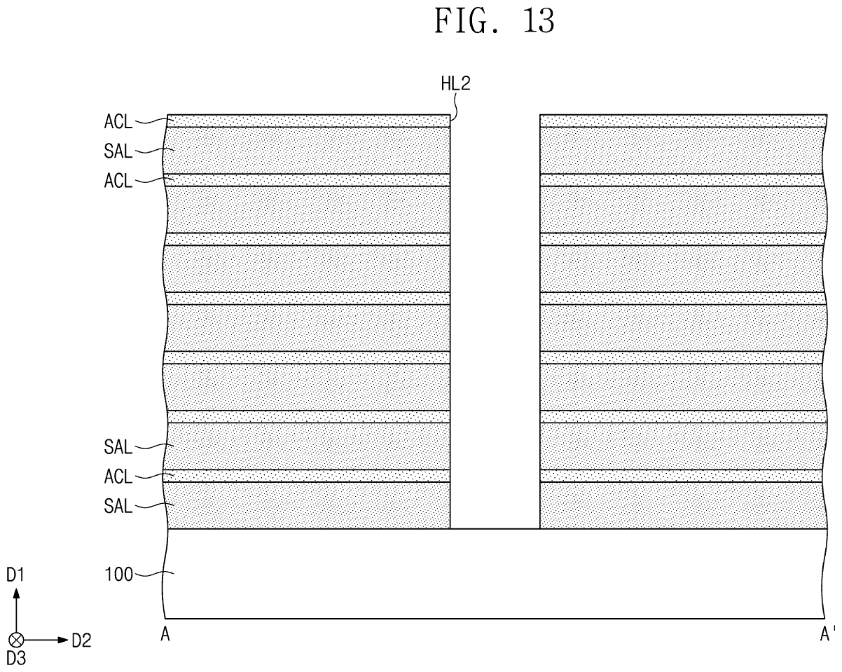

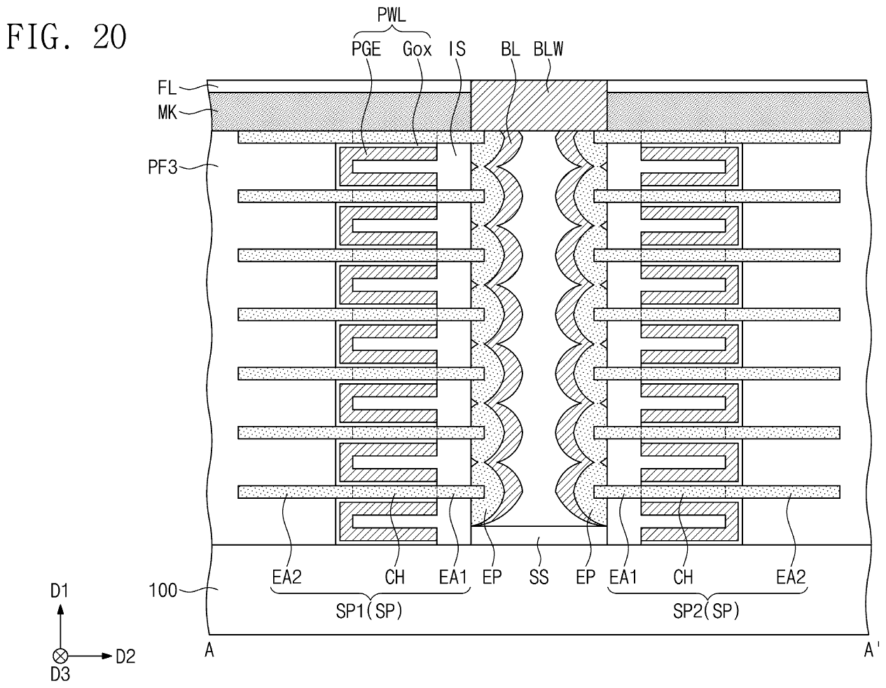

FIGS. 11 to 20 are diagrams illustrating a method of fabricating a three-dimensional semiconductor device, according to an embodiment of the inventive concept. In detail, FIGS. 11 and 20 are sectional views, each of which is taken along a line A-A′ of FIG. 3. FIGS. 12, 14, 16, and 18 are plan views illustrating a method of fabricating a three-dimensional semiconductor device, according to an embodiment of the inventive concept. FIGS. 13, 15, 17, and 19 are sectional views taken along lines A-A′ of FIGS. 12, 14, 16, and 18, respectively.

Referring to FIGS. 3 and 11, the substrate 100 may be prepared. Sacrificial layers SAL and active layers ACL may be formed to be alternatingly stacked on the substrate 100. Each of the sacrificial and active layers SAL and ACL may be formed of or include a semiconductor material. The sacrificial layers SAL may include a material having an etch selectivity with respect to the active layers ACL. Thus, even when the sacrificial layers SAL are removed, the active layers ACL may be hardly or less removed in a subsequent process of removing the sacrificial layers SAL. In an embodiment, the active and sacrificial layers ACL and SAL may be formed of or include at least one of silicon (Si), germanium (Ge), or silicon germanium (SiGe), but the material of the sacrificial layers SAL may be different from that of the active layers ACL. In an embodiment, the active layers ACL may be formed of or include silicon (Si), and the sacrificial layers SAL may be formed of or include silicon-germanium (SiGe). When measured in the first direction D1, a thickness of the sacrificial layers SAL may be larger than a thickness of the active layers ACL.

Referring to FIGS. 12 and 13, a portion of each of the sacrificial and active layers SAL and ACL may be removed to form first holes HL1 on the substrate 100. The first holes HL1 may be formed to be adjacent to each other in the second and third directions D2 and D3. A portion of the top surface of the substrate 100 may be exposed to the outside (i.e., externally exposed) through the first holes HL1. As a result of the removal process, the sacrificial and active layers SAL and ACL may be formed to include regions, which are elongated in the second direction D2, and regions, which are elongated in the third direction D3. The term “elongated” may refer to longitudinal extension along the described direction.

First preliminary filling patterns PF1 may be formed to cover the exposed portion of the top surface of the substrate 100 and to fill the first holes HL1. In an embodiment, the first preliminary filling pattern PF1 may include an insulating material. The first preliminary filling patterns PF1 may be formed to be adjacent to each other in the second and third directions D2 and D3.

Portions of the sacrificial and active layers SAL and ACL elongated in the third direction D3 may be removed to form second holes HL2 on the substrate 100. The second holes HL2 may extend in the third direction D3. Opposite side surfaces of the sacrificial and active layers SAL and ACL may be exposed to the outside through the second holes HL2. A portion of the top surface of the substrate 100 may be exposed to the outside through the second holes HL2.

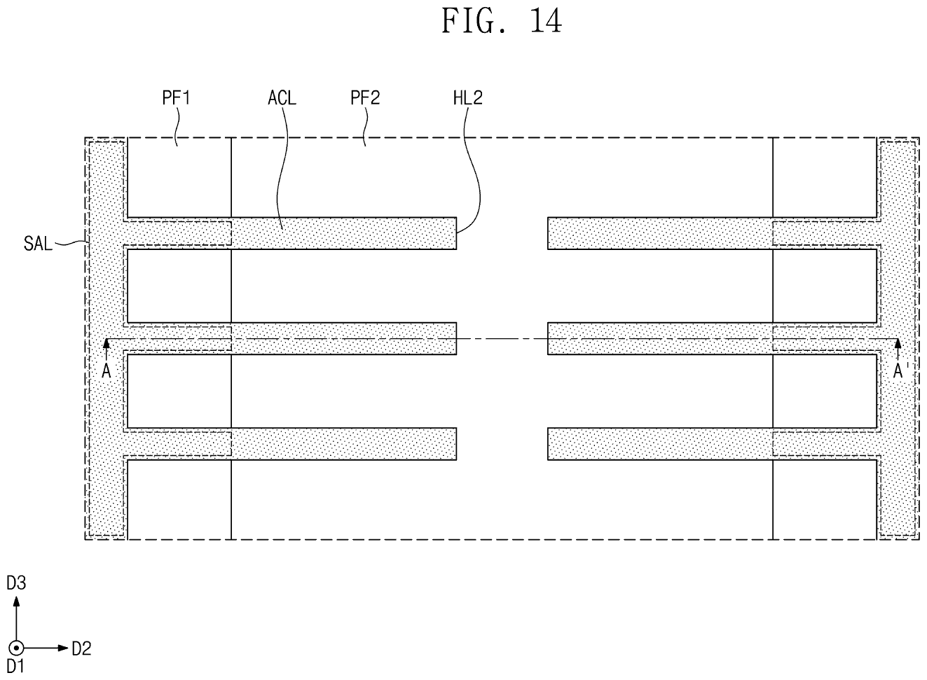

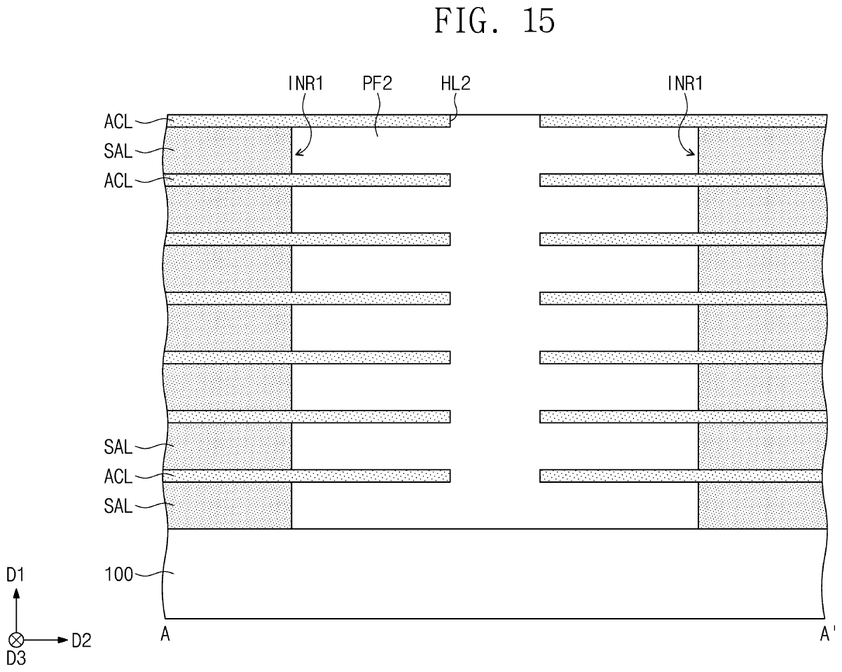

Referring to FIGS. 14 and 15, the exposed opposite side surfaces of the sacrificial layers SAL may be selectively removed through the second holes HL2. Thus, first inner regions INR1 may be formed between the active layers ACL arranged in the first direction D1. Each of the first preliminary filling patterns PF1 may also be partially removed during the removal process. Side surfaces of the first preliminary filling patterns PF1 may be aligned to side surfaces of the sacrificial layers SAL.

A second preliminary filling pattern PF2 may be formed to fill the first inner regions INR1, empty regions, which are formed by partially removing the first preliminary filling patterns PF1, and the second holes HL2. The second preliminary filling pattern PF2 may be provided to surround and cover the active layers ACL, which are not vertically overlapped with the sacrificial layers SAL. The second preliminary filling pattern PF2 may include a single or composite layer including an insulating material. In an embodiment, the second preliminary filling pattern PF2 may be formed of or include at least one of silicon oxide or silicon nitride.

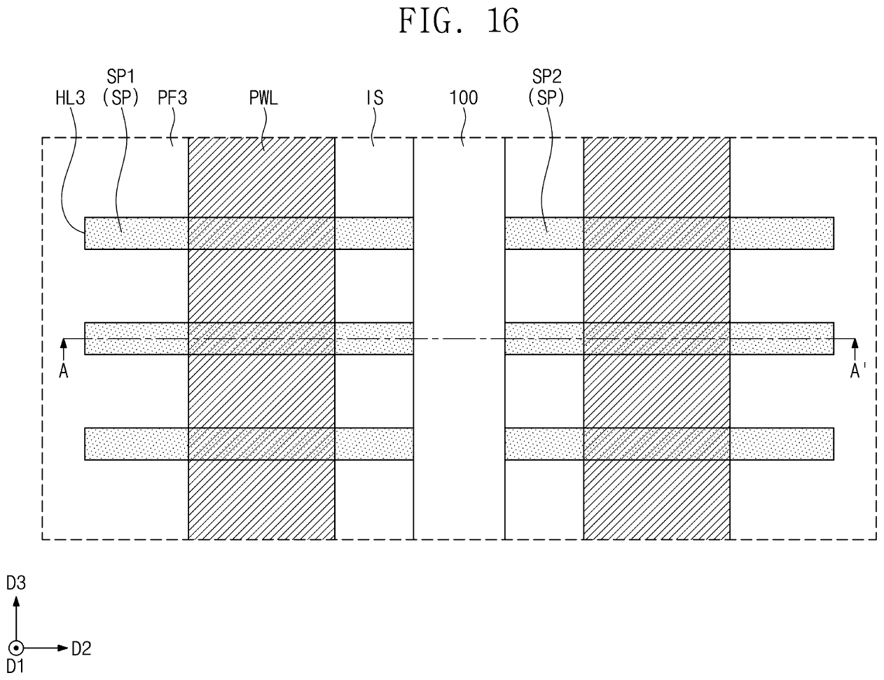

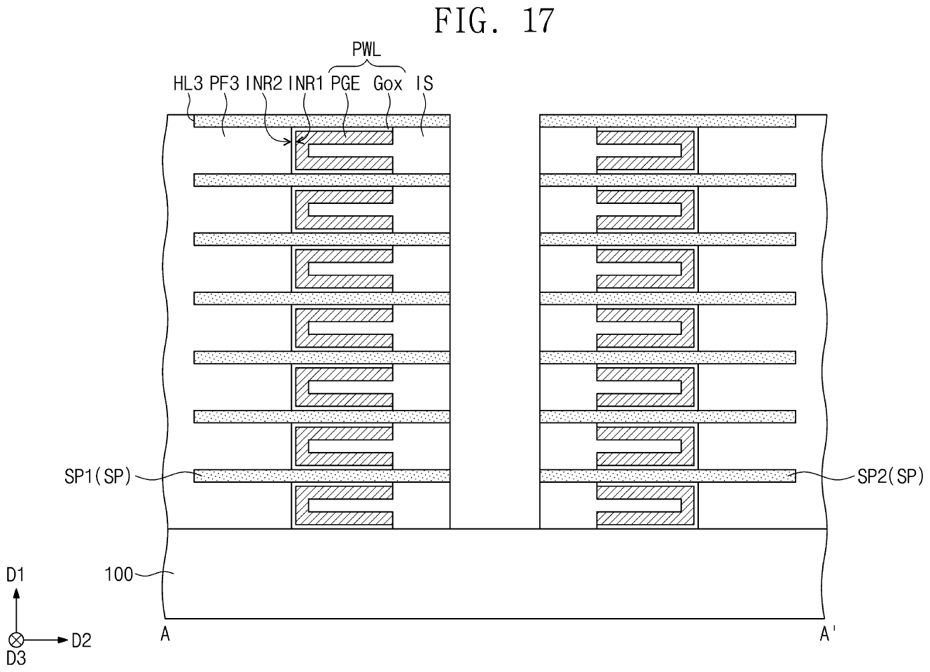

Referring to FIGS. 16 and 17, portions of the sacrificial and active layers SAL and ACL elongated in the third direction D3 may be removed to form a third hole HL3 on the substrate 100. During the process of forming the third holes HL3, the active layer ACL may be divided into the semiconductor patterns SP, which are adjacent to each other in the third direction D3. The semiconductor pattern SP may include the first semiconductor pattern SP1 and the second semiconductor pattern SP2, which are adjacent to each other in the second direction D2. During the process of forming the third holes HL3, the sacrificial layers SAL may be exposed to the outside again.

The exposed sacrificial layers SAL may be fully removed from the substrate 100 through the third holes HL3. Thus, second inner regions INR2 may be formed between regions of the active layers ACL, which are not overlapped with the second preliminary filling pattern PF2. During the removal process, the first preliminary filling patterns PF1 may be fully removed from the substrate 100. Thereafter, a third preliminary filling pattern PF3 may be formed to fill the second inner regions INR2, empty regions, which are formed by removing the first preliminary filling patterns PF1, and the third holes HL3. The third preliminary filling pattern PF3 may include a single or composite layer including an insulating material. In an embodiment, the third preliminary filling pattern PF3 may be formed of or include at least one of silicon oxide or silicon nitride.

Thereafter, the second preliminary filling pattern PF2 may be removed from the substrate 100. Next, the gate dielectric layer Gox and a preliminary gate conductive layer PGE may be sequentially formed in the first inner regions INR1 to constitute a preliminary word line PWL. The gate dielectric layer Gox and the preliminary gate conductive layer PGE may be sequentially formed to conformally cover a portion of the semiconductor pattern SP. The gate dielectric layer Gox and the preliminary gate conductive layer PGE may be formed to enclose and cover a portion of the semiconductor pattern SP. Each gate dielectric layer Gox and each preliminary gate conductive layer PGE may be formed to surround and cover a portion of each of the semiconductor patterns SP, which are adjacent to each other in the first and third directions D1 and D3. Next, the inner insulating layer IS may be formed in the first inner regions INR1 and an empty region, which is formed by removing the second preliminary filling pattern PF2.

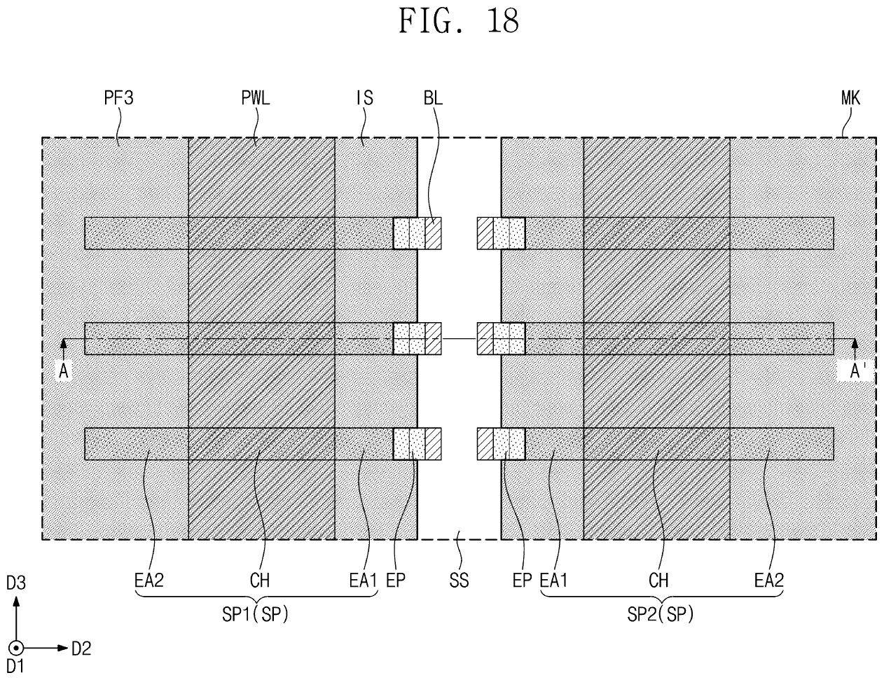

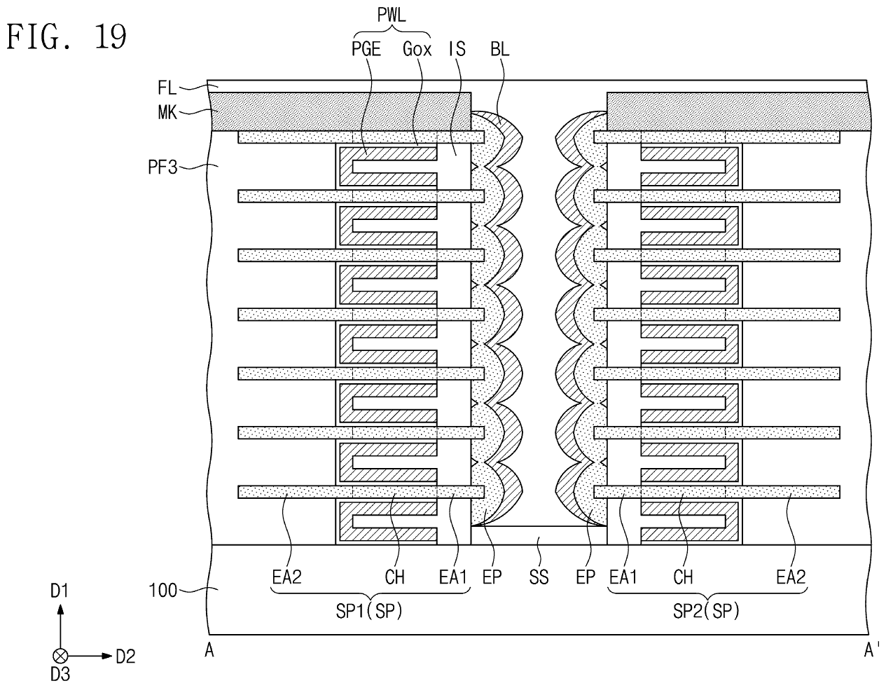

Referring to FIGS. 18 and 19, a mask pattern MK may be formed on the semiconductor pattern SP, the third preliminary filling pattern PF3, and the inner insulating layer IS. When viewed in a plan view, a side surface of the mask pattern MK may have concave surfaces, which are repeatedly provided in the third direction D3. That is, the side surface of the mask pattern MK may include a plurality of concave portions along the third direction D3. Each of the concave surfaces and a portion of the first edge portion EA1 of the corresponding semiconductor pattern SP may be exposed to the outside through the concave surfaces.

An indent process may be performed on the inner insulating layer IS. Thus, a portion of the inner insulating layer IS may be removed in a horizontal direction. Accordingly, top, bottom, and side surfaces of a portion of the first edge portion EA1 of the semiconductor pattern SP may be exposed to the outside. In an embodiment, the first edge portion EA1 of the semiconductor pattern SP may be partially removed during the removal process or through an additional removal process. Next, the separation pattern SS may be formed on the substrate 100.

The epitaxial pattern EP may be formed through a SEG process using the exposed portion of the first edge portion EA1 of each of the semiconductor patterns SP as a seed layer. In detail, the formation of the epitaxial pattern EP may include performing a SEG process using the first edge portion EA1 as a seed layer to form preliminary epitaxial patterns (not shown) on the first edge portions EA1 of the semiconductor patterns SP, respectively, and in this case, adjacent ones of the preliminary epitaxial patterns, which are grown through during the SEG process may be connected to each other. The preliminary epitaxial patterns, which are connected to each other, may form the epitaxial pattern EP.

Next, the bit line BL may be formed on a side surface of the epitaxial pattern EP. In an embodiment, the ohmic pattern OM described with reference to FIG. 5 may be formed between the epitaxial pattern EP and the bit line BL through the process of forming the bit line BL or an additional process.

Thereafter, the filling pattern FL may be formed on the separation pattern SS. The filling pattern FL may be formed to fill a region between the bit lines BL. The filling pattern FL may be formed to cover a top surface of the mask pattern MK.

Referring to FIGS. 3 and 20, a portion of the filling pattern FL may be removed to form an empty region, and the bit line wire BLW may be formed in the empty region. In an embodiment, during the removal process, each of the epitaxial pattern EP and the bit line BL may also be partially removed.

Referring to FIGS. 3 and 4, the filling pattern FL, the mask pattern MK, and the third preliminary filling pattern PF3 may be removed from the substrate 100. During the removal process of the third preliminary filling pattern PF3, the gate dielectric layer Gox and the preliminary gate conductive layer PGE may also be removed. Thus, each gate dielectric layer Gox may be divided into a plurality of gate dielectric layers Gox, which are adjacent to each other in the first and third directions D1 and D3. In addition, each preliminary gate conductive layer PGE may be divided into a plurality of gate electrodes GE, which are adjacent to each other in the first and third directions D1 and D3. The gate dielectric layer Gox and the gate electrode GE may constitute the word line WL.

The capping pattern CP may be formed to fill the second inner regions INR2 described with reference to FIGS. 3 and 20 and an empty region formed by removing the third preliminary filling pattern PF3. Thereafter, a portion of the capping pattern CP may be removed, and the second edge portions EA2 of the semiconductor patterns SP may be exposed to the outside.

A removal process may be performed on a portion of the exposed second edge portions EA2 of the semiconductor patterns SP. During the removal process, a portion of the first capping pattern CP1 may also be removed.

The storage electrodes SE may be formed on the second edge portions EA2 of the semiconductor patterns SP. The formation of the storage electrodes SE may include forming silicide patterns (not shown) on the second edge portions EA2 of the semiconductor patterns SP and forming the storage electrodes SE through a SEG process using the silicide patterns as a seed layer.

A removal process may be performed on a portion of the second capping pattern CP2. Thus, a side surface of the second capping pattern CP2 may be aligned to a side surface of the second edge portion EA2 of the semiconductor pattern SP. Thereafter, the capacitor dielectric layer CIL may be formed to conformally cover the storage electrodes SE. The plate electrode PE may be formed to fill a space between the storage electrodes SE. The storage electrode SE, the capacitor dielectric layer CIL, and the plate electrode PE may constitute the data storage pattern DSP. Thereafter, the protection layer PL may be formed to cover the cell array structure CS.

According to an embodiment of the inventive concept, an epitaxial pattern may be formed through a selective epitaxial growth (SEG) process using semiconductor patterns as a seed layer, and the semiconductor patterns may be connected to each other through the epitaxial pattern. Thus, even when an additional patterning process is not performed, the semiconductor patterns may be electrically connected to a bit line through the epitaxial pattern. As a result, it may be possible to reduce a process failure, which may occur in a patterning process for forming the bit line. Thus, the productivity or production yield of the three-dimensional semiconductor device may be improved.

While example embodiments of the inventive concept have been particularly shown and described, it will be understood by one of ordinary skill in the art that variations in form and detail may be made therein without departing from the scope of the attached claims.

What is claimed is:

1. A three-dimensional semiconductor device, comprising:
a plurality of semiconductor patterns stacked in a first direction perpendicular to a top surface of a substrate and extending in a second direction parallel to the top surface of the substrate, each of the semiconductor patterns comprising a first end portion and a second end portion that is opposite the first end portion;
a plurality of word lines on the semiconductor patterns and extending in a third direction that is parallel to the top surface of the substrate and intersects the second direction;
a data storage pattern on the second end portions of the semiconductor patterns and extending in the first direction; and
an epitaxial pattern on the first end portions of the semiconductor patterns and extending in the first direction,
wherein the semiconductor patterns are connected to each other by the epitaxial pattern.

2. The three-dimensional semiconductor device of claim 1, wherein the epitaxial pattern comprises at least one convex portion that protrudes in the second direction.

3. The three-dimensional semiconductor device of claim 2, wherein the at least one convex portion comprises a plurality of convex portions that protrude in the second direction from the first end portions of the semiconductor patterns, and are arranged along the first direction.

4. The three-dimensional semiconductor device of claim 1, wherein a side surface of the epitaxial pattern has an undulating profile in the first direction.

5. The three-dimensional semiconductor device of claim 1, wherein a portion of each of the semiconductor patterns extends into the epitaxial pattern in the second direction.

6. The three-dimensional semiconductor device of claim 1, further comprising:
an inner insulating layer between the semiconductor patterns; and
a plurality of air gaps between the inner insulating layer and the epitaxial pattern,
wherein the air gaps are arranged along the first direction.

7. The three-dimensional semiconductor device of claim 1, further comprising:
a protection layer on the data storage pattern; and
a bit line wire in the protection layer,
wherein the semiconductor patterns are electrically connected to the bit line wire by the epitaxial pattern.

8. The three-dimensional semiconductor device of claim 1, wherein the epitaxial pattern comprises at least one of silicon (Si) or silicon germanium (SiGe).

9. The three-dimensional semiconductor device of claim 1, wherein an atomic concentration of germanium in the epitaxial pattern increases with distance from the semiconductor patterns.

10. The three-dimensional semiconductor device of claim 1, wherein the epitaxial pattern contains n-type impurities.

11. The three-dimensional semiconductor device of claim 1, further comprising:
a bit line on a side surface of the epitaxial pattern and extending in the first direction.

12. The three-dimensional semiconductor device of claim 11, further comprising:
an ohmic pattern extending in the first direction between the epitaxial pattern and the bit line.

13. The three-dimensional semiconductor device of claim 12, wherein the ohmic pattern extends in the first direction in an undulating shape.

14. The three-dimensional semiconductor device of claim 11, wherein a side surface of the bit line has an undulating profile in the first direction.

15. A three-dimensional semiconductor device, comprising:
a plurality of semiconductor patterns that are stacked in a first direction perpendicular to a top surface of a substrate and extend in a second direction parallel to the top surface of the substrate, each of the semiconductor patterns comprising a first end portion and a second end portion that is opposite the first end portion;
a plurality of word lines on the semiconductor patterns and extending in a third direction that is parallel to the top surface of the substrate and intersects the second direction;
a data storage pattern on the second end portions of the semiconductor patterns and extending in the first direction;
an epitaxial pattern on the first end portions of the semiconductor patterns and extending in the first direction; and
a bit line wire on a top surface of the epitaxial pattern,
wherein the semiconductor patterns are connected to the bit line wire by the epitaxial pattern.

16. The three-dimensional semiconductor device of claim 15, wherein the epitaxial pattern comprises a plurality of convex portions that protrude in the second direction from the first end portions of the semiconductor patterns, and
the convex portions are arranged along the first direction.

17. The three-dimensional semiconductor device of claim 15, wherein a side surface of the epitaxial pattern has an undulating profile in the first direction.

18. The three-dimensional semiconductor device of claim 15, wherein the epitaxial pattern comprises at least one of silicon (Si) or silicon germanium (SiGe).

19. The three-dimensional semiconductor device of claim 15, further comprising:
a bit line on a side surface of the epitaxial pattern and extending in the first direction,
wherein the bit line is electrically connected to the bit line wire.

20. A three-dimensional semiconductor device, comprising:
a substrate,
a first stack and a second stack on the substrate, wherein the first stack and the second stack are adjacent to one another in a second direction that is parallel to a top surface of the substrate,
wherein the first stack comprises:
a plurality of semiconductor patterns that are stacked in a first direction perpendicular to the top surface of a substrate and extend in the second direction, each of the semiconductor patterns comprising a first end portion and a second end portion that is opposite the first end portion;
a plurality of word lines on the semiconductor patterns and extending in a third direction that is parallel to the top surface of the substrate and intersects the second direction;
a data storage pattern on the second end portions of the semiconductor patterns and extending in the first direction; and
an epitaxial pattern on the first end portions of the semiconductor patterns and extending in the first direction,
wherein the semiconductor patterns are connected to each other by the epitaxial pattern.
